(19) United States
(12) Patent Application Publication
(10) Pub. No.: US 2016/0313427 A1
(43) Pub. Date: Oct. 27, 2016

(54) FAST THREE DIMENSIONAL T2 WEIGHTED BALANCED STEADY-STATE FREE PRECESSION IMAGING

(71) Applicant: THE REGENTS OF THE UNIVERSITY OF CALIFORNIA, Oakland, CA (US)

(72) Inventors: Daniel B. Ennis, Manhattan Beach, CA (US); Subashini Srinivasan, Los Angeles, CA (US); Holden H. Wu, Los Angeles, CA (US)

(73) Assignee: THE REGENTS OF THE UNIVERSITY OF CALIFORNIA, Oakland, CA (US)

(21) Appl. No.: 15/136,753

(22) Filed: Apr. 22, 2016

Related U.S. Application Data
(60) Provisional application No. 62/152,094, filed on Apr. 24, 2015.

(51) Int. Cl. G01R 33/56; G01R 33/561; G01R 33/48

(52) U.S. Cl. CPC G01R 33/5602; G01R 33/4822; G01R 33/5614

(57) ABSTRACT

A fast 3D T₂₋weighted imaging system and method is disclosed that uses balanced steady state free precession (bSSFP), variable flip angles, and an interleaved multi-shot spiral-out phase encode ordering strategy to acquire high resolution T₂-weighted images quickly while maintaining spatial resolution.

### CROSS-REFERENCE TO RELATED APPLICATIONS

This application claims priority to, and the benefit of, U.S. provisional patent application Ser. No. 62/152,094 filed on Apr. 24, 2015, incorporated herein by reference in its entirety.

### STATEMENT REGARDING FEDERALLY SPONSORED RESEARCHOR DEVELOPMENT

Not Applicable

### INCORPORATION-BY-REFERENCE OF COMPUTER PROGRAM APPENDIX

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND

1. Technical Field

This description pertains generally to medical imaging, and more particularly to fast 3D T₂-weighted imaging.

2. Background Discussion

T₂ weighted prostate MRI is the clinical standard for anatomic imaging of the prostate and is routinely performed using fast spin echo techniques (e.g. FSE, TSE, or RARE). Three dimensional (3D) T₂ weighted prostate imaging is preferred for imaging small tumors and for acquiring near isotropic slices that are amenable to multi-planar reformatting, which is useful for multi-modal registration applications during biopsy, surgical, or treatment planning.

The conventional 2D FSE sequences use a series of 180° refocusing pulses with a long repetition time for signal recovery to produce purely T₂ weighted images. The use of 180° pulses increases the specific absorption rate (SAR) of the sequence, particularly at 3T, and the number of acceptable refocusing pulses is further limited due to fast signal decay and concomitant image blurring. These disadvantages can be overcome by designing variable flip angle (VFA) schemes that use refocusing flip angles (FA)<180° for T₂ weighted FSE. However, three-dimensional T₂ weighted FSE prostate imaging, can take over 7 minutes to acquire even with a VFA scheme.

Balanced steady state free precession (bSSFP) imaging is widely used for numerous clinical applications due to its high signal to noise ratio (SNR) efficiency. However, the steady-state signal of bSSFP is T₂/T₁ weighted, which is not desirable for clinical applications where the underlying abnormality may vary in both T₁ and T₂. 2D single-shot T₂ weighted imaging has previously been demonstrated using SSFP techniques such as 2D T₂-TIDE and 2D T₂ VAPSIF based on the Transition Into Driven Equilibrium (TIDE) sequence. Extension of these techniques to 3D encoding schemes, however, is not practical because of the SAR limitation that arises from the long acquisition durations, particularly for short pulse repetition times (TR) at higher field strengths (≧3T).

### BRIEF SUMMARY

An aspect of the present description is a fast 3D T₂ weighted imaging techniques that uses balanced steady state free precession (bSSFP), variable flip angles, and an interleaved, multi-shot, spiral-out phase encode ordering strategy to acquire high resolution T₂-weighted images faster than previous techniques while maintaining spatial resolution.

One preferred embodiment uses bSSFP imaging, which has a higher SNR efficiency compared to spin echo based sequences (3D SPACE, 3D XETA). The k-space acquisition trajectory of this sequence is also different compared to the above sequences that may enable faster 3D acquisition compared to linear acquisitions. Interleaved spiral-out phase encode ordering is central to the success of our technology. The number of interleaves or the number of shots (Nshot) is a controllable parameter in 3D T₂-TIDE unlike other spin-echo techniques. For example, if the Nshot is decreased, the images can be acquired even faster but at the cost of broader point spread function or increased image blurriness.

Three dimensional (3D) T₂ weighted magnetic resonance imaging (MRI) is preferred for anatomic imaging of small tumors and for acquiring thin slices that are amenable to multi-planar reformatting, which is useful, for example, for multi-modal registration applications during biopsy, surgical or treatment planning for many cancers.

Another aspect is a fast 3D T₂ weighted imaging techniques that uses balanced steady state free precession (bSSFP) and incorporates a 2D T₂-TIDE-like variable flip angle (FA) scheme and an efficient 3D acquisition scheme (TWIST) (interleaved spiral-out phase encode ordering). The transient bSSFP signal is T₂ weighted and is used to acquire the low spatial frequencies (center of k-space), hence conferring T₂-weighting. The higher spatial frequencies (outer k-space lines) are acquired with a steady-state signal that is T₂/T₁ weighted akin to using variable flip angles as in 2D T₂-TIDE. The 3D k-space is filled using an interleaved spiral-out phase encode ordering in k_{y}-k_{z} plane enabling efficient acquisition of the transient signal in the center of the k-space. A multi-shot (Nshot) interleaved trajectory may also be employed to improve the image sharpness while maintaining T₂-weighting.

In another aspect, a system is provided for fast 3D T₂ weighted TIDE (3D T₂-TIDE) bSSFP imaging with application to prostate imaging at 3T.

The 3D T₂-TIDE system of the present description uses a VFA scheme similar to 2D T₂-TIDE to reduce the SAR and maintain the T₂ contrast by acquiring the central k-space lines first during the transient state with a flip angle lower than 180°, followed by ramping down to a lower FA while acquiring the outer k-space lines. The 3D T₂-TIDE images are acquired faster than 3D FSE by using a spiral-out phase encode ordering in the k_{y}-k_{z} plane of the 3D Cartesian k-space trajectory to efficiently sample the central 3D k-space lines with T₂ contrast. Image sharpness is improved by implementing a multi-shot interleaved acquisition scheme. This k-space acquisition scheme also eliminates the need for partial Fourier acquisitions to control the T₂ weighting as done for 2D T₂-TIDE or 3D FSE. Furthermore, the acquisition of outer k-space lines with a lower FA steady-state bSSFP approach permits extended echo train durations compared to FSE.

Further aspects of the technology will be brought out in the following portions of the specification, wherein the detailed description is for the purpose of fully disclosing preferred embodiments of the technology without placing limitations thereon.

### BRIEF DESCRIPTION OF THE SEVERAL VIEWS OF THE DRAWING(S)

The technology described herein will be more fully understood by reference to the following drawings which are for illustrative purposes only:

FIG. 1A shows an image of a simulated signal of the 50^{th} echo and FA=60° for a range of T₁ values from 100 ms to 3000 ms in steps of 100 ms and range of T₂ values from 30 ms to 300 ms in steps of 50 ms.

FIG. 1B shows a plot of the percent signal difference between the signal in FIG. 1A and pure T₂ decay simulated with T₁=5000 ms.

FIG. 2 shows a flow diagram for a method for performing fast 3D T₂ weighted imaging in accordance with the present description.

FIG. 3 shows a block diagram illustrating an exemplary flip angle (FA) scheme of interleaved 3D T₂-TIDE sequencing in accordance with the method of the present description.

FIG. 4 shows a schematic diagram of a system for performing fast 3D T₂-weighted imaging in accordance with the present description.

FIG. 5A through FIG. 5D show a plots of a simulation of tissue with T1/T2=1500/150 ms, with FIG. 5A at Nₛₕₒₜ=1 illustrating the FA variation along spiral sampling in ky-kz plane, generating a signal shown in the plot of FIG. 5B and the corresponding plot of FA in FIG. 5C and signal for Nₛₕₒₜ=24 in FIG. 5D.

FIG. 6 shows a plot of a simulation of contrast (signal difference) between tissues with T₁/T₂=1500/150 ms and T₁/T₂=1500/100 ms for a range of α_{high} from 10° to 180° and range of Nₚᵣₑₚ from 1 to 150 pulses. The maximum contrast of 0.15 is achieved by spin echo sequencing using α_{high} of 180° and Nₚᵣₑₚ=26, however cannot be achieved by using a α_{high} lower than 180°. The contrast of 0.08 corresponding to spin echo sequence with α_{high}=180° and Nₚᵣₑₚ=7 may be achieved with a lower α_{high}=74° with Nₚᵣₑₚ=51 pulses.

FIG. 7 shows a plot illustrating signal evolution of prostate tissue, muscle, and fat for a single shot with α_{high}=60°, α_{low}=30°, Nₚᵣₑₚ=50, N_{high}=20 and Nₚᵣₑₚ=200. The fat signal was simulated with an off-resonant frequency of 440 Hz but the other tissues were simulated at on-resonance. The dashed lines represent samples with T₂ values identical to the solid lines but with long T₁=5000 ms.

FIG. 8A and FIG. 8B show images acquired via 2D PSF for Nₛₕₒₜ=1 and Nₛₕₒₜ=48, respectively, for a tissue with T₁/T₂=1500/150 ms, Nk_{y}=230, Nk_{z}=48, α_{high}=60°, α_{low}=30°, Nₚᵣₑₚ=50, N_{high}=20, Nᵣₐₘₚ=200.

FIG. 9A and FIG. 9B show the line profiles of PSF in logarithmic scale along the center of the y- and z-directions, respectively, for 3D steady-state bSSFP signal for Nₛₕₒₜ values of 1, 16, 24 and 48. Interleaved (multi-shot) acquisition has reduced side lobes and hence improved sharpness compared to Nₛₕₒₜ=1.

FIG. 10A through FIG. 10D show single slice images comparing axial prostate images acquired in a healthy subject using clinical 3D FSE (FIG. 10A), 3D T₂-TIDE (FIG. 10B), 2D multi-slice FSE (FIG. 10C) and 3D bSSFP (FIG. 10D). The 3D T₂-TIDE images are T₂ weighted similar to 3D FSE and 2D multi-slice FSE with clear delineation of the prostate “capsule”.

FIG. 11A through FIG. 11C show single slices from 3D T₂-TIDE images acquired with different T₂ weighting by changing Nₚᵣₑₚ to 10, 50 and 100, respectively. Higher Nₚᵣₑₚ results in increased T₂ weighting.

FIG. 11D through FIG. 11F show 3D T₂-TIDE images acquired with different Nₛₕₒₜ=1 values of 1, 16, and 48, respectively, and associated sharpness. Higher Nₛₕₒₜ results in sharper images due to the improvement in PSF.

FIG. 12 shows a series of images comparing the acquisition of 3D T₂-TIDE (bottom row) to 3D FSE (top row) acquired in the axial plane and reformatted into the coronal and sagittal planes.

### DETAILED DESCRIPTION

The following description details fast 3D T₂ weighted imaging systems and methods that utilize balanced steady state free precession (bSSFP), variable flip angles, and an interleaved multi-shot spiral-out phase encode ordering strategy to acquire high resolution T₂-weighted images. A technical discussion is first provided outlining the physics behind the technology of the present description, followed by a description and methods to perform the imaging techniques of the present technology, and experimental results from an exemplary embodiment of the technology.

A. Technical Discussion.

The decay of the transient signal (M_{xy}) for on-resonance spins in bSSFP, with perfectly balanced gradients and a preparation pulse of α/2 applied for a duration of TR/2 can be expressed as Eq. 1:

$${M}_{xy} ( n ) = ( sin ( \frac{α}{2} ) {M}_{0} - {M}_{ss} ) {λ}^{n} + {M}_{ss} ; \qquad Eq . 1$$

where n is the echo number, α is the flip angle, M₀ is the proton density, M_{SS} is the steady-state bSSFP signal, and the decay rate (λ) of the transient signal is given as Eq. 2:

$$λ = {E}_{2} {sin}^{2} ( α / 2 ) + {E}_{1} {cos}^{2} ( α / 2 ) \\ with \\ {E}_{1 , 2} = exp ( - \frac{TR}{{T}_{1 , 2}} ) . \qquad Eq . 2$$

Note that λ is purely T₂ weighted if α=180°. However, a 180° flip angle is not practical for extended echo trains due to SAR limitations. T₂-weighting, however, can also be attained when TR/T₁˜0 (e.g., E₁˜1). This approximation holds at higher field strengths due to the increased T₁, and when using a short TR (preferred when using bSSFP to reduce off-resonance induced banding artifacts and improve sequence efficiency).

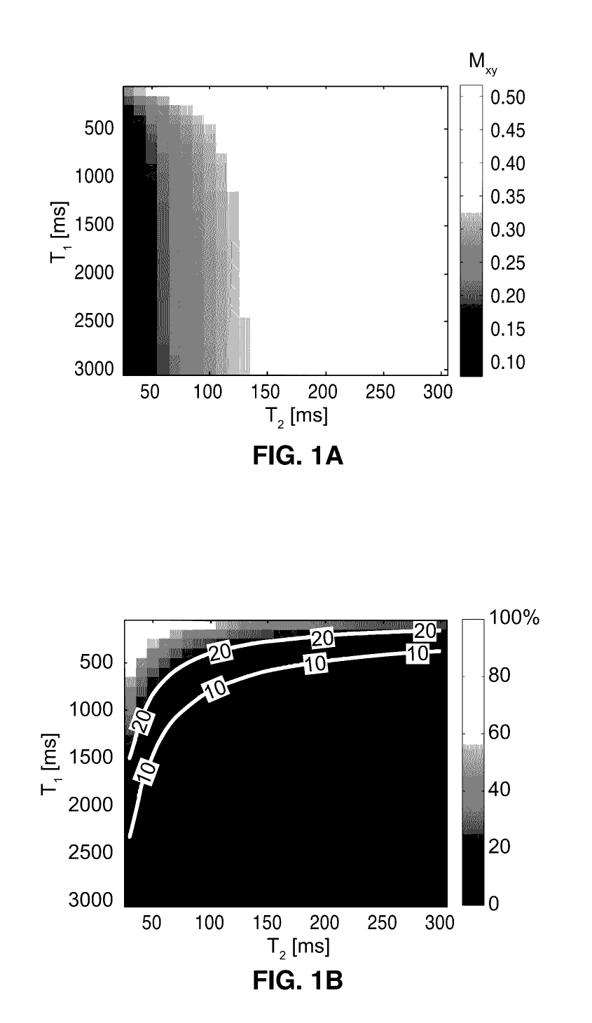

FIG. 1A shows a simulation image of the bSSFP transient signal for the 50^{th} echo with TR=4.84 ms, TE=2.42 ms, and α=60° for a broad range of T₁ (100 ms to 3000 ms) and a broad range of T₂ (30 ms to 300 ms). The 50^{th} echo was chosen to demonstrate the achievable contrast for the chosen T₂.

FIG. 1B shows a plot of the percent signal change between the simulations shown in FIG. 1A and the simulation for the pure T₂ decay signal, which was simulated with T₁=5000 ms to ensure TR/T₁˜0 (i.e. E₁˜1). Iso-contours (white curves) for 10% and 20% signal differences are highlighted. Note that as T₁ and T₂ decrease, the percent signal difference becomes larger. Hence for prostate tissues with T₁˜1500 ms, the percent signal difference is 15% for T₂=50 ms and decreases with increasing T₂. Thus, for tissues with longer T₁ values, the T₂ weighting is similar to pure T₂ decay. However, as T₁ and T₂ values become shorter, the T₂ weighting of the signal decreases.

B. Systems and Methods for 3D T₂-TIDE Image Acquisition.

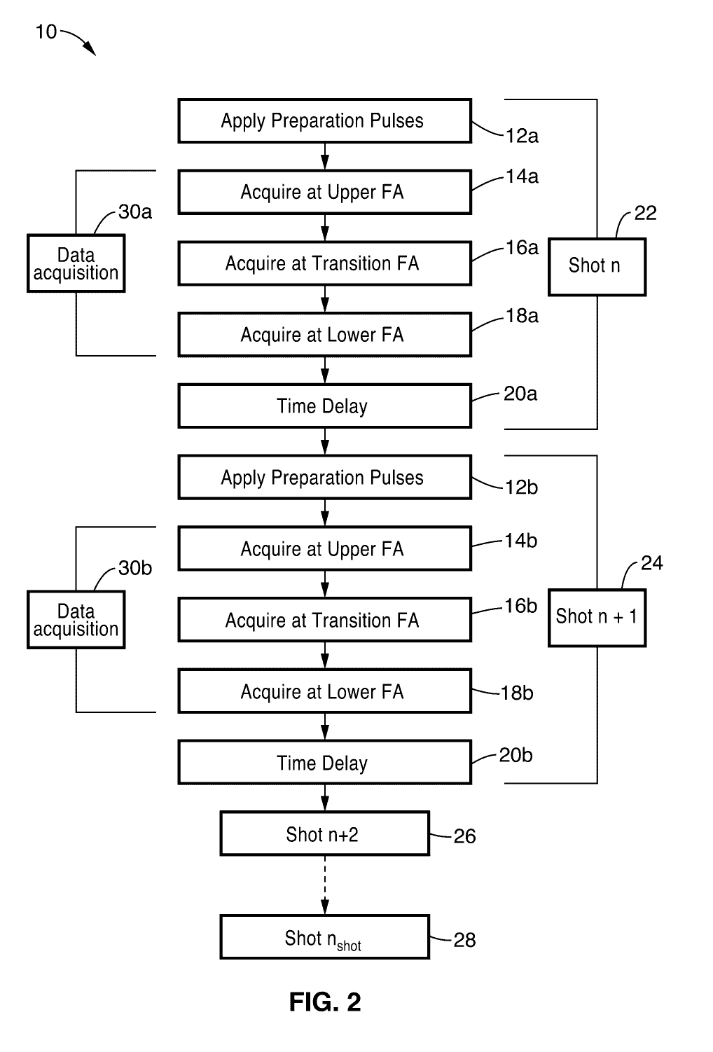

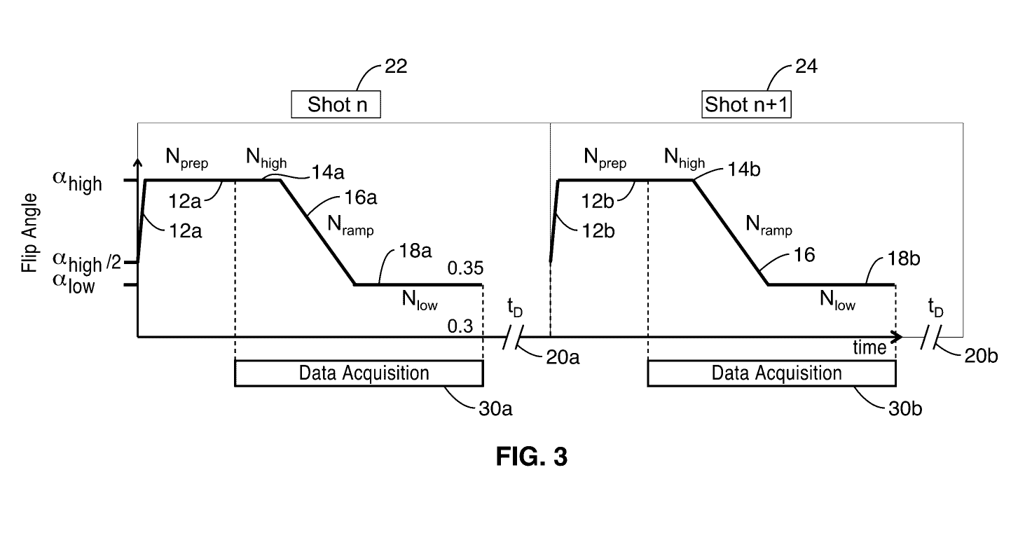

FIG. 2 and FIG. 3 show schematic diagrams illustrating an exemplary method 10 of performing a flip angle (FA) scheme of interleaved 3D _{T2}-TIDE sequencing in accordance with the method of the present description.

As seen in FIG. 2 and FIG. 3, sequencing is performed via a plurality of interleaves or “shots” (e.g. shot n 22 through shot nₛₕₒₜ 28 where nₛₕₒₜ is the total number of shots). Starting with the first shot n (22), preparation pulses 12a are first generated. A first preparation pulse (at a flip angle between 0° and α_{high}/2) is followed by subsequent ramping preparation pulses at increasing flip angles until preparation pulse(s) (Nₚᵣₑₚ at α_{high}) are reached to control the T₂ weighting of the image. Increasing Nₚᵣₑₚ increases the T₂ weighting.

Data acquisition 30a is then performed to acquire images of target tissue, starting with N_{high} pulses at an upper flip angle (FA) α_{high} at block 14a to maintain the T₂ contrast and weighting of the image. Acquisition pulses and are then smoothly ramped down during a transition phase at block 16a until acquisition is performed at lower flip angle α_{low} at block 18a to reduce the SAR. The α_{high} is lower in the 3D T₂-TIDE compared to 2D T₂-TIDE (α_{high}=180°) to reduce the SAR for 3D acquisitions in addition to maintaining the _{T2} contrast.

A time delay (t_{D}) 20a is included after data acquisition 30a of shot 22 (and each subsequent shot), which allows for recovery of the longitudinal magnetization (M_{z}) before acquisition of the subsequent shot (e.g. shot n+1 (24)).

Shot n+1 (24) is then performed starting with preparation pulses 12b. As with the first shot first preparation pulse (α_{high}/2) is followed by a second preparation pulse (Nₚᵣₑₚ at α_{high}) to control the T₂ weighting of the image. Increasing Nₚᵣₑₚ increases the T₂ weighting.

Data acquisition 30b is then performed to acquire images of target tissue, starting with N_{high} pulses at an upper flip angle (FA) α_{high} at block 14b to maintain the T₂ contrast and weighting of the image. Acquisition pulses and are then smoothly ramped down during a transition phase at block 16b until acquisition is performed at lower flip angle α_{low} at block 18b to reduce the SAR.

A time delay (t_{D}) 20b is included after data acquisition 30b of shot 24. Shot n+2 (26) is then performed, essentially repeating the steps of shot 24. This process is repeated until the total number of shots x is reached.

In a preferred embodiment, the image acquisition duration of 3D T₂-TIDE is made faster by acquiring the 3D Cartesian k-space in the k_{y}-k_{z} plane using a spiral-out phase encode ordering. The acquisition pattern is configured to first acquire the 3D central k-space lines at initial T2-weighted steps (e.g. step n 22 and immediate subsequent steps with α_{high}), thereby maintaining the T₂ contrast, and moving outward with subsequent n+ steps in a spiral pattern to the high spatial frequency k-space lines, which are acquired with the steady-state bSSFP signal and decrease toward concomitant T₂/T₁ weighting. Such multi-shot or interleaved spiral-out phase encoded ordering within the k_{y}-k_{z} plane is performed to distribute the transition of the transient signal across a broader range of spatial frequencies, thereby improving the sharpness of the image compared to single-shot approaches, albeit at the cost of increased scan time.

In a preferred embodiment, the number of interleaves, i.e. the number of shots, nₛₕₒₜ, is a controllable parameter in the 3D T2-TIDE system, unlike other spin-echo techniques. For example, if the number of shots x is decreased, the images can be acquired even faster, but at the cost of broader point spread function or increased image blurriness.

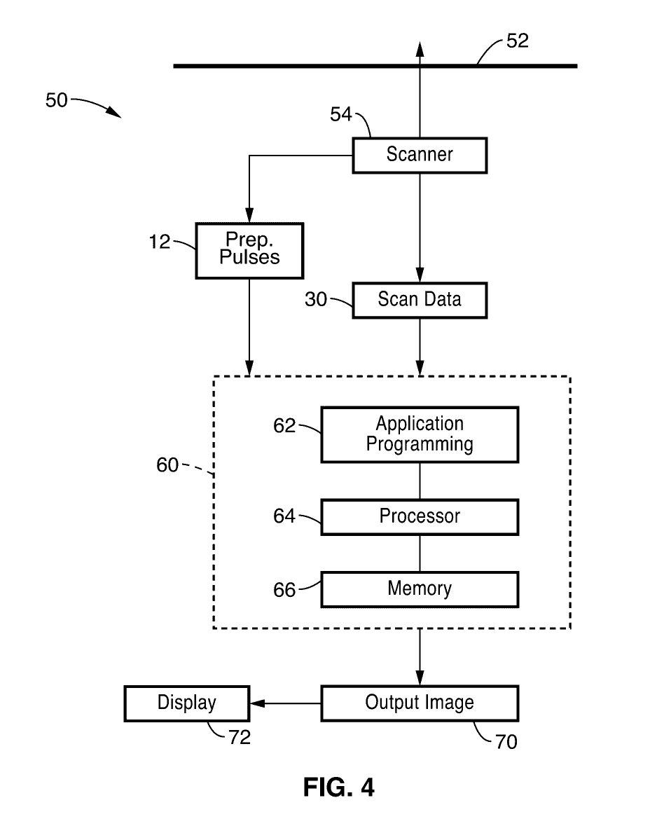

FIG. 4 shows a schematic diagram of a system 50 for performing fast 3D T2 weighted imaging in accordance with the present description. Scanner 54, e.g. MRI scanner acquires scan data 32 of a target tissue 52. The scan data 30 and prep pulses 12 are input into computing device 60 (e.g. computer, server) comprising processor 64 and application programming 62 stored in memory 66 for execution on the processor 64. Programming comprises instructions for carrying out the steps of method 10 shown in FIG. 2 and FIG. 3 to transform the raw scan data 30 into the enhanced output image 70 for output on a display 72 or like device.

1. Bloch Simulations.

In order to understand parameter selection, image contrast, and spatial resolution, Bloch equation simulations of the 3D T₂-TIDE sequence 10 were performed in MATLAB (The Mathworks, Natick, Mass.). Simulations of the transverse magnetization (M_{xy}) for bSSFP were performed for normal prostate tissue with T₁/T₂=1500/150 ms, TR/TE=4.84/2.42 ms, Nk_{y}=230, Nk_{z}=48, α_{high}=60, α_{low}=30, Nₚᵣₑₚ=50, N_{high}=20, Nᵣₐₘₚ=200, and t_{D}=1635 ms for number of shots (Nₛₕₒₜ)=1 and Nₛₕₒₜ=24. These simulation parameters are identical to that of the subsequent 3D T₂-TIDE in vivo imaging experiments shown in Table 1. The signal profile within the k_{y}-k_{z} plane was generated by combining the simulated single-shot or multi-shot signal with the generated k_{y}-k_{z} spiral-out phase encoding trajectory pattern. In Table 1, the phase encoding (PE) direction of A to P indicates Anterior to Posterior and R to L indicates Right to Left.

The maximum contrast between normal prostate tissue with T₁/T₂=1500/150 ms and prostate tumor tissue with T₁/T₂=1500/100 ms was determined by performing signal difference simulations with a constant FA scheme (α_{high}=α_{low}) for a range of α_{high} values, varying from 10° to 180° and Nₚᵣₑₚ=1 to 150 with TR/TE=4.84/2.42 ms. These simulations were performed to determine the Nₚᵣₑₚ required for maximum signal contrast with the maximum achievable α_{high} determined by the SAR limitations.

The T₁ contributions to the 3D T₂-TIDE signal were simulated for prostate tissue with T₁/T₂=1500/150 ms, muscle tissue (T₁/T₂=900/30 ms) and fat tissue (T₁/T₂=382/68 ms with off-resonance of 440 Hz) using the imaging parameters identical to the previous simulations. The signal evolution for each echo was compared to pure T₂ weighted simulations with identical T₂ values, but with long T₁=5000 ms, which ensures TR/T₁˜0 (i.e., E₁˜1 in Eqn. 2).

The effect of Nₛₕₒₜ on the point spread function (PSF) was determined by simulating the signal (M_{xy}) for normal prostate tissue using imaging parameters identical to the 3D T₂-TIDE in vivo imaging experiments (Table 1) and Nₛₕₒₜ=1, 16, 24, and 48. The multi-shot PSF was also compared to the PSF of 3D steady-state bSSFP signal. The inverse Fourier transform of the signal resulted in the 2D PSF in k_{y}-k_{z} plane for each Nₛₕₒₜ.

2. In Vivo Imaging.

All images were acquired on a 3T scanner (Trio, Siemens Medical Solutions, Erlangen, Germany) using a six-channel anterior coil and six-channel posterior spine matrix for prostate imaging. Prostate images were acquired in 10 healthy male subjects (N=10, age: 29±5 years) using 3D FSE, 2D multi-slice FSE, 3D T₂-TIDE, and 3D bSSFP to compare their signal differences. The imaging parameters for each of these acquisitions are summarized in Table 1. Separate noise scans with identical imaging parameters without applied RF pulses were acquired for 3D FSE and 3D T₂-TIDE sequences to estimate the standard deviation of the noise for signal to noise ratio (SNR) calculations.

Images were also acquired with different Nₚᵣₑₚ=10, 25, 60 and 100 with constant Nₛₕₒₜ=24 in a subset of five healthy subjects to demonstrate the different T₂ weighting achievable with 3D T₂-TIDE. The dependence of the PSF on Nₛₕₒₜ was demonstrated by acquiring 3D T₂-TIDE images with different values of Nₛₕₒₜ=1, 2, 4, 8, 16, 24 and 48 with constant Nₚᵣₑₚ=50. The other imaging parameters for these acquisitions were identical to the 3D T₂-TIDE acquisition parameters mentioned in Table 1, except the phase encoding direction was changed to anterior to posterior with 0-13% phase oversampling based on the subject and without GRAPPA, averages, and partial Fourier.

3. In Vivo Data Analysis.

The SNR was calculated as the ratio of the mean signal to standard deviation of the noise from the noise scan in five different regions: peri-prostatic fat, gluteal fat, left peripheral zone, right peripheral zone, and anterior fibromuscularstroma. The SNR was divided by

$$\sqrt{\frac{2}{4 - π}} = 1.53$$

to account for the Rayleigh distribution of the noise. The regions of interest (ROIs) were drawn in a single slice of the 3D FSE images for each of the 10 healthy subjects and copied to the identical slice in 3D T₂-TIDE and their corresponding noise scans. This was performed by a radiologist having read over 1000 prostate MRI studies. The SNR efficiency was calculated as the ratio of the SNR to the square root of the acquisition duration in minutes. The CNR was calculated between the anterior fibromuscularstroma and the peripheral zone as the difference between their SNR, the anterior fibromuscularstroma being consistently low signal and peripheral zone high signal in normal subjects. The SNR of the peripheral zone was calculated as the average of the SNRs of the left and right peripheral zone. The CNR efficiency was calculated as the ratio of the CNR to the square root of the acquisition duration in minutes. A statistical comparison between the SNR efficiency of the 3D FSE and 3D T₂-TIDE was calculated using a paired Student t-test for the five different regions with P<0.05. The t-test values were Holm-Sidakpost-hoc corrected.

C. Experimental Results.

1. Simulation Results.

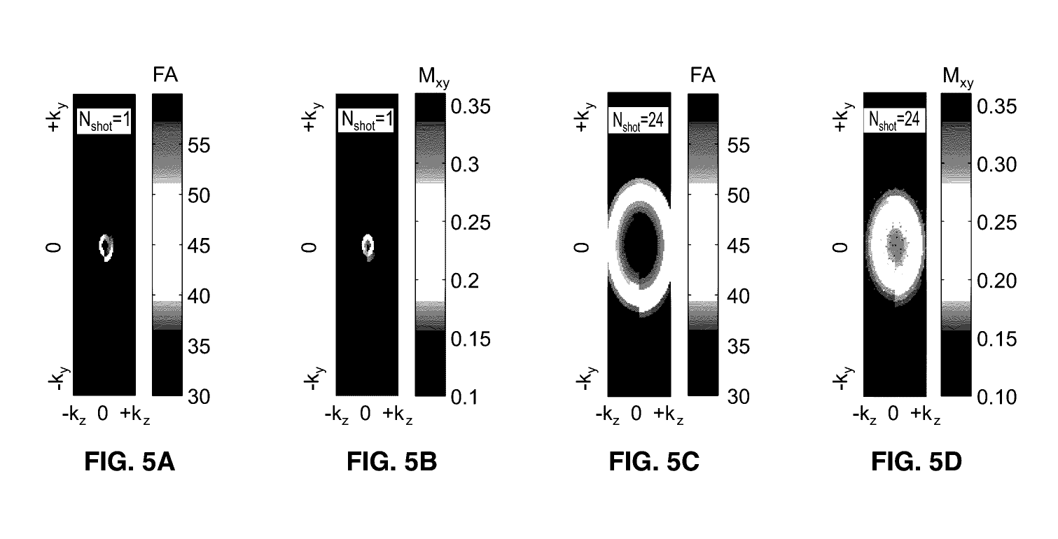

Simulated 3D T₂-TIDE images of the signal in the k_{y}-k_{z} plane were generated using the VFA scheme of FIG. 2 and FIG. 3 with interleaved spiral-out phase encode ordering in the k_{y}-k_{z} plane. For simulated prostate tissue, the signal (M_{xy}) in the k_{y}-k_{z} plane for Nₛₕₒₜ=1 and the corresponding VFA scheme (FIG. 5A and FIG. 5B) shows that the center of 3D k-space was acquired with the transient bSSFP signal and the outer k-space lines were acquired with the steady-state bSSFP signal. The corresponding signal and FA scheme for Nₛₕₒₜ=24 are shown in FIG. 5C and FIG. 5D. Multi-shot 3D T₂-TIDE was used to increase the percent of the central k_{y}-k_{z} phase encodes acquired with the transient signal.

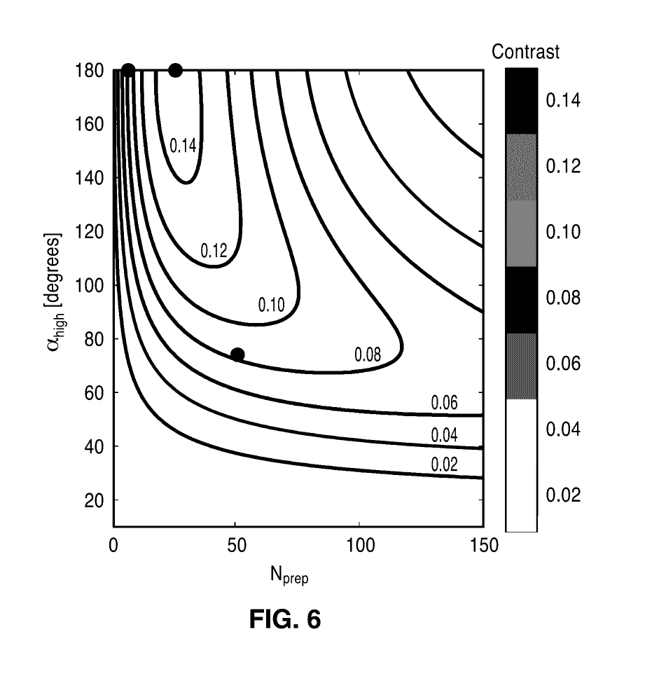

The T₂ contrast of the 3D T₂-TIDE images was governed by the choice of α_{high} and Nₚᵣₑₚ that were used to specify the VFA scheme. FIG. 6 shows the transient bSSFP signal simulation of the contrast between the normal prostate tissue and tumor tissue for a range of α_{high} and Nₚᵣₑₚ. The simulation with α_{high}=180° corresponds to the T₂ contrast achievable in a spin echo sequence by varying the effective TE (i.e. Nₚᵣₑₚ). The α_{high} used for the 3D T₂-TIDE acquisitions was determined by the SAR limitation at 3T. Hence, for a given α_{high}, Nₚᵣₑₚ can be chosen by following the contrast curve from α_{high}=180° to the achievable α_{high}. For example, by choosing α_{high}=74° and Nₚᵣₑₚ=51, contrast of 0.08 is produced, which is also achievable using α_{high}=180° and Nₚᵣₑₚ=7 (shown as the left and lower dots in FIG. 6). The upper right dot indicates the maximum contrast achieved using α_{high}=180°, which cannot be obtained by using a α_{high}<180°, but a very similar contrast can be attained with α_{high} as low as 140°.

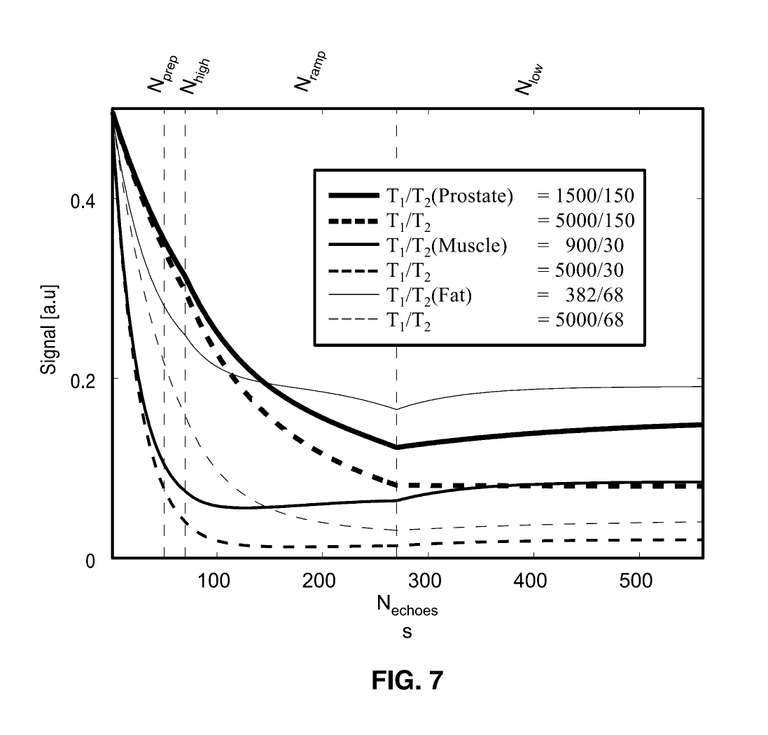

FIG. 7 shows the signal evolution of the transient signal for prostate tissue, muscle, and fat (with off-resonance) and compares their respective signal evolutions to tissues with identical T₂ values, but with long T₁=5000 ms in order to simulate pure T₂ decay. When N_{echoes}=Nₚᵣₑₚ, the transient signal for prostate tissue (T₁=1500 ms) and muscle (T₁=900 ms) are similar to the pure T₂ decay due to their long T₁. The fat signal (T₁=382 ms), however, is higher in 3D T₂-TIDE compared to pure T₂ decay as a consequence of both the short T₁ and off-resonance.

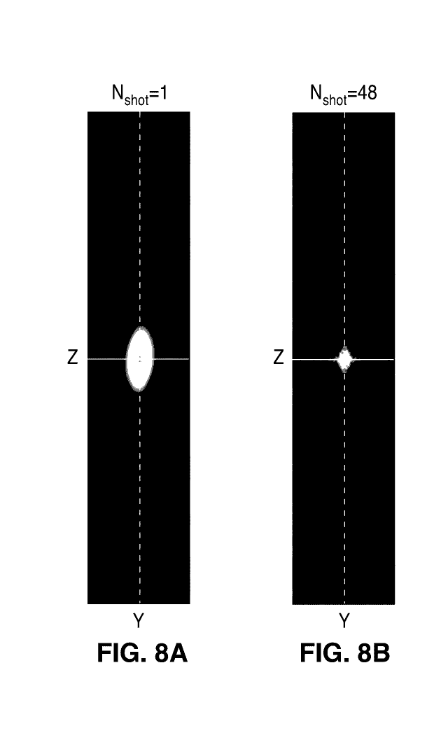

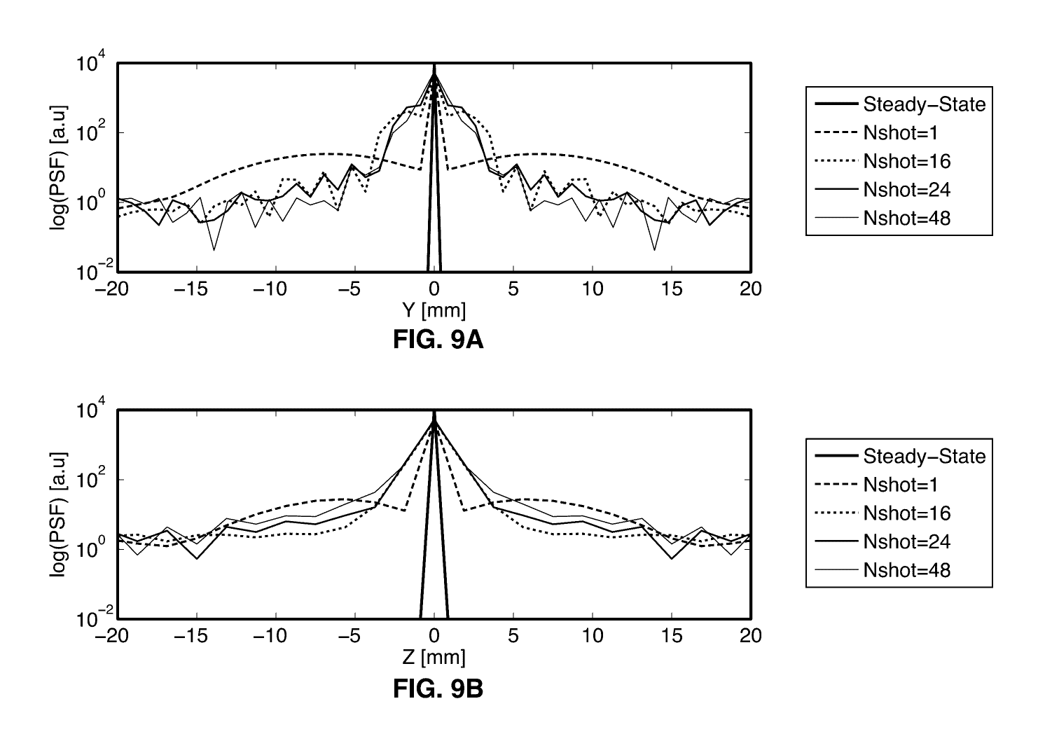

The PSF of the 3D T₂-TIDE images was improved by increasing Nₛₕₒₜ. FIG. 8A and FIG. 8B show the simulation of the 2D PSF for Nₛₕₒₜ=1 and Nₛₕₒₜ=48. The line profiles along the center of the y- and z-directions for 3D steady-state bSSFP signal for Nₛₕₒₜ values of 1, 16, 24 and 48 are shown in FIG. 9A and FIG. 9B. The side lobes of the PSF decreases with increasing Nₛₕₒₜ, which shows that increasing Nₛₕₒₜ improves the PSF along the y direction, albeit at the cost of extended scan times. Similar to the y-direction, the side lobes of the multi-shot acquisitions are attenuated in the z-direction compared to Nₛₕₒₜ=1. However, the main lobes of the multi-shot acquisitions are similar to each other.

2. In Vivo Results.

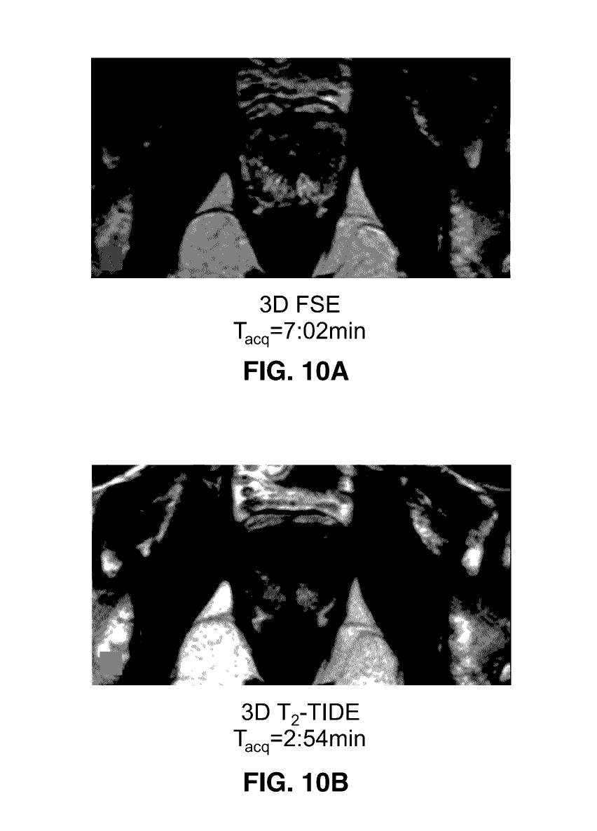

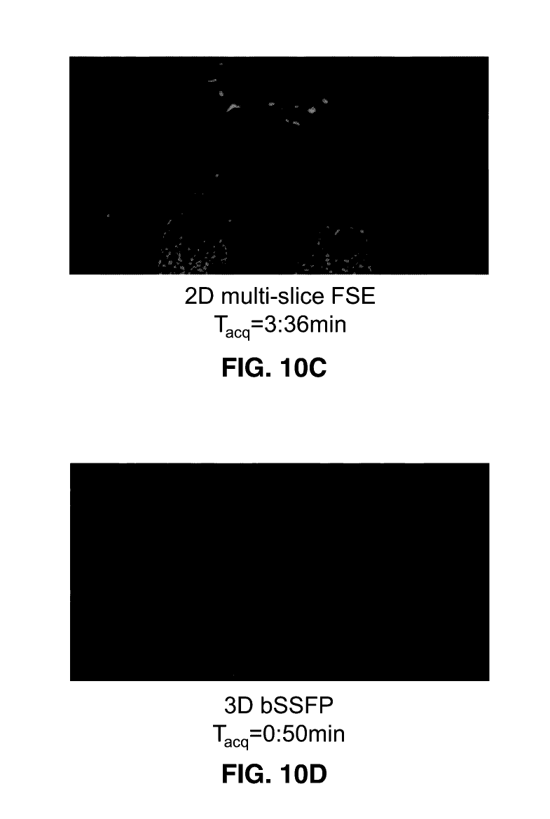

FIG. 10A through FIG. 10D show images comparing axial prostate images acquired in a healthy subject using 3D FSE (FIG. 10A), 3D T₂-TIDE (FIG. 10B), 2D multi-slice FSE (FIG. 10C) and 3D bSSFP (FIG. 10D). The 3D T₂-TIDE images are T₂ weighted similar to 3D FSE and 2D multi-slice FSE with clear delineation of the prostate “capsule”. The acquisition duration of 3D T₂-TIDE (FIG. 10B) was 2:54 minutes compared to 3D FSE (FIG. 10A) acquisition duration of 7:02 minutes. Compared to the T₂ weighted images, the 3D bSSFP images show that the contrast between the anterior fibro muscular stroma and the peripheral zone and tissue signal heterogeneity within the prostate are qualitatively reduced.

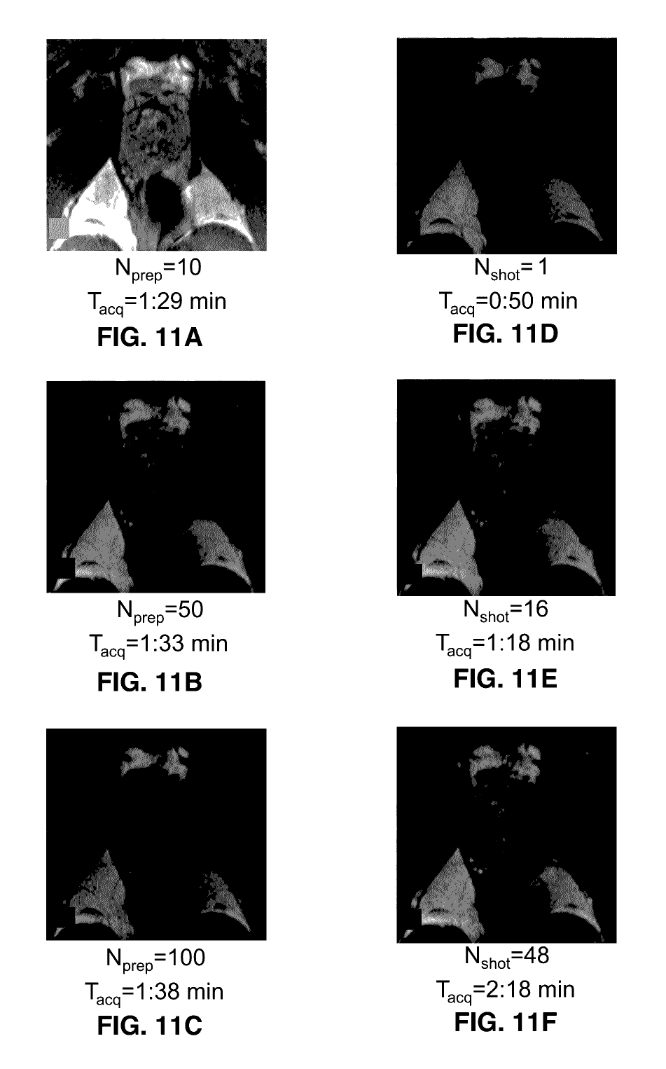

FIG. 11A through FIG. 11C show 3D T₂-TIDE images acquired with different T₂ weighting by changing Nₚᵣₑₚ to 10, 50 and 100, respectively. Lower Nₚᵣₑₚ results in reduced T₂ contrast with similar image sharpness, whereas increasing Nₚᵣₑₚ improves T₂ contrast. All images have the same window level. FIG. 11D through FIG. 11F show 3D T₂-TIDE images acquired with varying Nₛₕₒₜ values of 1, 16 and 48, respectively. The delineation of the prostate “capsule” is improved with increasing Nₛₕₒₜ due to improvement in the PSF, but with a penalty of increased acquisition duration as shown in each figure.

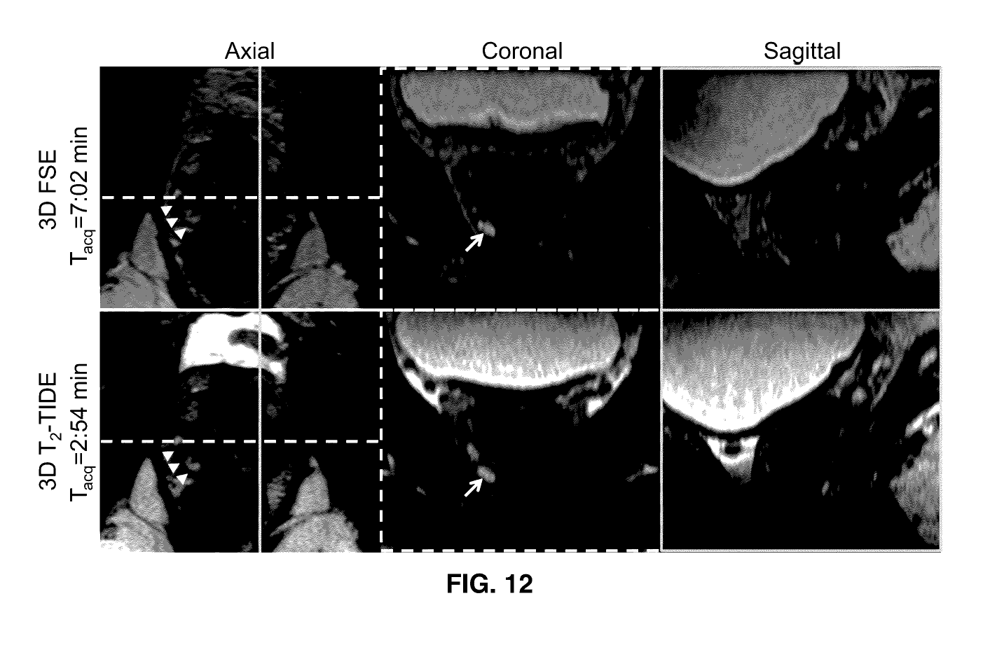

FIG. 12 shows a series of images comparing the acquisition of 3D T₂-TIDE to 3D FSE for images acquired in the axial plane and reformatted into the coronal and sagittal planes. Overall, the image quality and contrast is very similar, but the 3D T₂-TIDE images are acquired significantly faster. In particular, it is noted that the prostate “capsule” (three arrows) is clearly depicted in both of these acquisitions in all the imaging planes. The reformatted images in coronal and sagittal plane also show good definition of features such as cystic benign nodule (single arrow) within the prostate. The iso-volumetric resolution allows for improved fidelity in multimodal image fusion and multi-planar reformations may obviate the need for acquisition of additional pulse sequences to visualize those planes.

The SNR efficiency of 3D T₂-TIDE was compared to 3D FSE in five different regions from images acquired in the healthy subjects (N=10). The SNR efficiency in all measured tissues: peri-prostatic fat=45±12 vs. 31±7 (P<0.01), gluteal fat=48±8 vs. 41±10 (P=0.12), right peripheral zone=20±4 vs. 16±8 (P=0.12), left peripheral zone=17±2 vs. 12±3 (P<0.01), and anterior fibro muscular stroma=12±4 vs. 4±2 (P<0.01). The SNR efficiency of the anterior fibro muscular stroma, peri-prostatic fat and left-peripheral zone was significantly higher in 3D T₂-TIDE compared to 3D FSE. The CNR efficiency between the anterior fibro muscular stroma and peripheral zone using 3D T₂-TIDE was 10±6 and for 3D FSE it was 16±8 (P=0.03).

D. Summary.

3D T₂-TIDE was developed and evaluated for fast 3D T₂-weighted prostate imaging at 3T. It was demonstrated that images with an acquisition duration of 2:54 minutes compared very favorably to 3D FSE with an acquisition duration of 7:02 minutes and matched imaging parameters. The 3D T₂-TIDE images were acquired during the transient state of the bSSFP signal to control the T₂ weighting with multi-shot spiral-out phase encode ordering in the k_{y}-k_{z} plane of the 3D Cartesian trajectory, which enabled acquisition of the central k-space during the transient signal and the outer k-space during the steady state of bSSFP. This approach balanced maintaining T₂ weighting, preserving image resolution, and fast scanning.

In principle, pure T₂ weighting (identical to a spin echo) is possible with bSSFP imaging during the transient state with FA=180°. 3D imaging with FA=180° for extended echo trains with short TRs, however, is not possible at high field strengths (≧3T) due to the SAR limitation. 3D T₂ weighting is still possible with FA<180° if the tissue T₁ is long compared to TR. Bloch simulation with FA=60° (as illustrated in FIG. 1A and FIG. 1B) showed that the images will be T₂ weighted for long T₁ values with minimal percent signal difference compared to pure T₂ weighted signal. As both the T₁ and T₂ shorten, the T₂ contrast between tissues decreases.

The 3D T₂-TIDE signal profile in the first shot is higher than the signal profile in the subsequent shots which is visible, in the signal simulation of Nₛₕₒₜ=24, as speckles in FIG. 5D. This occurs because of the duration used for the 3D T₂-TIDE signal to reach a dynamic steady state between the shots. The effect of the high signal in the first shot compared to the subsequent shots was analyzed by acquiring 3D T₂-TIDE prostate images in healthy subjects using a discarded preparation shot. These images were compared to identical 3D T₂-TIDE acquisitions without discarding the first shot and the no qualitative effects on the image quality were observed. Hence, all the 3D T₂-TIDE in vivo images were acquired without the discarded shot in order to scan faster.

The maximum T₂ contrast achieved with α_{high}=180° will be higher than the maximum contrast that is achieved using a lower FA (α_{high}=60°) (as illustrated in FIG. 6). Hence, the CNR and the CNR efficiency between the anterior fibro muscular stroma and the peripheral zone was reduced using 3D T₂-TIDE (α_{high}=60°) compared to 3D FSE (α=110°). However, there was no loss of the difference between high signal in the peripheral zone and low signal in the anterior fibromuscularstroma and “capsule” qualitatively.

The 3D T₂-TIDE images were acquired during the transient state of the bSSFP signal to maintain the T₂ contrast. However, as the signal is not constant during the k-space filling, the PSF of 3D T₂-TIDE is broader compared to the 3D bSSFP imaging (as illustrated in FIG. 8A and FIG. 8B). The PSF is also dependent on the Nₛₕₒₜ and the spiral-out phase encode trajectory pattern in the Cartesian k_{y}-k_{z} plane. Due to the lower resolution along the z-direction compared to the y-direction, the choice of Nₛₕₒₜ impacts the PSF along y and z differently (as illustrated in FIG. 9A and FIG. 9B). The algorithm may be modified for sampling the spiral-out pattern on the k_{y}-k_{z} Cartesian grid, which may improve the PSF in the y- and z-direction uniformly. Bloch simulations may be configured for configuring a VFA scheme that produces constant bSSFP transverse magnetization. Similar simulations may be used to configure VFA schemes that reduce the slope of transient bSSFP signal for 3D T₂-TIDE imaging, thereby improving the PSF.

The T₂ contrast in FSE sequences is mainly controlled by the partial Fourier factor. The effective TE can be further reduced by the use of parallel imaging. In 3D T₂-TIDE, however, the T₂ contrast is controlled by Nₚᵣₑₚ and does not depend on the parallel imaging and partial Fourier factors. Herein, the in vivo 3D T₂-TIDE experiments used both partial Fourier and parallel imaging factors identical to 3D FSE for fair comparison of acquisition duration and SNR between these sequences. The spiral-out phase encode ordering in the k_{y}-k_{z} Cartesian plane of 3D T₂-TIDE enables the use of Nₛₕₒₜ≦N_{kz}, unlike other conventional 3D linear techniques using Nₛₕₒₜ≧N_{kZ}. For example, if the Nₛₕₒₜ is decreased, the images can be acquired even faster but at the cost of broader PSF or increased image blurriness. This may be useful for monitoring 3D T₂ changes during interventional procedures.

Prostate images are clinically acquired in the axial plane with phase encoding along the right to left (RL) direction to reduce rectal motion artifacts, which occur predominantly in the anterior to posterior direction. As the FOV in RL direction is ˜2× larger than the FOV in AP direction, the acquisition duration for the 3D prostate imaging is nearly doubled compared to swapping the phase and frequency axes. If the phase encoding duration is chosen to be along the AP direction, then the acquisition duration of 3D T₂-TIDE can be further reduced to 1:33 min (as illustrated in FIG. 11B), which may reduce the prevalence of the apparent rectal motion artifacts and may limit the need for glucagon.

While the description above and drawings are primarily directed to the use of 3D T₂-TIDE for fast 3D T₂ weighted imaging of the prostate, it is appreciated that the system and methods disclosed herein may also be used on applications of 3D T₂ weighted imaging for various anatomical regions of the body, including, but not limited to, the brain, abdomen, breast, uterine tumors, spine, ganglion cysts, ankle, knee, etc.

The interleaved multi-shot 3D T₂-TIDE acquisition with spiral-out phase encode ordering in k_{y}-k_{z}, improves the PSF by increasing the distribution of the transient signal in the middle of k_{y}-k_{z}. However, due to the delay between subsequent shots, any motion that occurs between shots may result in motion artifacts because the central k-space lines are partly acquired with each shot. In some embodiments, oversampling of the central k_{y}-k_{z} space may reduce artifacts due to inter-shot motion.

In sum, 3D T₂-TIDE can be used for fast 3D T₂ weighted prostate imaging at 3T with acceptable image quality and ˜58% reduction in acquisition duration compared to 3D FSE. The flexibility afforded by an interleaved shot strategy in 3D T₂-TIDE enables trade-offs between acquisition speed and image sharpness.

Embodiments of the present technology may be described with reference to flowchart illustrations of methods and systems according to embodiments of the technology, and/or algorithms, formulae, or other computational depictions, which may also be implemented as computer program products. In this regard, each block or step of a flowchart, and combinations of blocks (and/or steps) in a flowchart, algorithm, formula, or computational depiction can be implemented by various means, such as hardware, firmware, and/or software including one or more computer program instructions embodied in computer-readable program code logic. As will be appreciated, any such computer program instructions may be loaded onto a computer, including without limitation a general purpose computer or special purpose computer, or other programmable processing apparatus to produce a machine, such that the computer program instructions which execute on the computer or other programmable processing apparatus create means for implementing the functions specified in the block(s) of the flowchart(s).

Accordingly, blocks of the flowcharts, algorithms, formulae, or computational depictions support combinations of means for performing the specified functions, combinations of steps for performing the specified functions, and computer program instructions, such as embodied in computer-readable program code logic means, for performing the specified functions. It will also be understood that each block of the flowchart illustrations, algorithms, formulae, or computational depictions and combinations thereof described herein, can be implemented by special purpose hardware-based computer systems which perform the specified functions or steps, or combinations of special purpose hardware and computer-readable program code logic means.

Furthermore, these computer program instructions, such as embodied in computer-readable program code logic, may also be stored in a computer-readable memory that can direct a computer or other programmable processing apparatus to function in a particular manner, such that the instructions stored in the computer-readable memory produce an article of manufacture including instruction means which implement the function specified in the block(s) of the flowchart(s). The computer program instructions may also be loaded onto a computer or other programmable processing apparatus to cause a series of operational steps to be performed on the computer or other programmable processing apparatus to produce a computer-implemented process such that the instructions which execute on the computer or other programmable processing apparatus provide steps for implementing the functions specified in the block(s) of the flowchart(s), algorithm(s), formula(e), or computational depiction(s).

It will further be appreciated that the terms “programming” or “program executable” as used herein refer to one or more instructions that can be executed by a processor to perform a function as described herein. The instructions can be embodied in software, in firmware, or in a combination of software and firmware. The instructions can be stored local to the device in non-transitory media, or can be stored remotely such as on a server, or all or a portion of the instructions can be stored locally and remotely. Instructions stored remotely can be downloaded (pushed) to the device by user initiation, or automatically based on one or more factors. It will further be appreciated that as used herein, that the terms processor, computer processor, central processing unit (CPU), and computer are used synonymously to denote a device capable of executing the instructions and communicating with input/output interfaces and/or peripheral devices.

From the description herein, it will be appreciated that that the present disclosure encompasses multiple embodiments which include, but are not limited to, the following:

1. An apparatus for performing fast three dimensional (3D) T2 weighted imaging of a target tissue, comprising: (a) a computer processor; and (b) a non-transitory computer-readable memory storing instructions executable by the computer processor; (c) wherein said instructions, when executed by the computer processor, perform steps comprising: (i) acquiring image data from a target tissue site with at least one interleaved imaging shot; (ii) said imaging shot comprising data acquisition via one or more pulses directed at the target tissue at a first flip angle (α_{high}) and one or more pulses directed at the target tissue at a second flip angle (α_{low}); (iii) wherein the first flip angle (α_{high}) is larger than the second flip angle (α_{low}), and the first flip angle (α_{high}) is less than 180°; and (iv) generating a 3D T₂-weighted image from the acquired image data as a function of the at least one interleaved shot.

2. The apparatus of any preceding embodiment, wherein the shot comprises a plurality of ramping pulses to smoothly ramp down from the first flip angle to the second flip angle.

3. The apparatus of any preceding embodiment, wherein the image data is acquired in 3D Cartesian k-space in a ky-kz plane to encode the target tissue using a spiral-out phase encode ordering.

4. The apparatus of any preceding embodiment, wherein spiral-out phase encode ordering comprises an acquisition pattern configured to initially acquire centrally located 3D low spatial frequency k-space lines, and subsequently moves outward in a spiral pattern to acquire high spatial frequency k-space lines.

5. The apparatus of any preceding embodiment: wherein outer-most k-space lines are acquired with a steady-state free precession (bSSFP) signal and concomitant T₂/T₁ weighting; and wherein centrally-located k-space lines are acquired with transient bSSFP signal and T₂ weighting.

6. The apparatus of any preceding embodiment, wherein the low frequency k-space lines are acquired with at flip angle of α_{high}.

7. The apparatus of any preceding embodiment: wherein image data is acquired with a plurality of interleaved shots; and wherein the number of interleaved shots is a controllable parameter configured to improve a point spread function (PSF) of the generated image.

8. The apparatus of any preceding embodiment: wherein the shot further comprises a series of preparation pulses prior to acquiring the image data; the series of preparation pulses having a flip angle that increases to one or more preparation pulses at a flip angle of α_{high}.

9. The apparatus of any preceding embodiment, wherein the series of preparation pulses ramps from a preparation pulse starting at a flip angle between 0° and α_{high/2} followed with a series of preparation pulses at increasing flip angles that are followed by one or more preparation pulses at a flip angle of α_{high}.

10. The apparatus of any preceding embodiment, wherein the shot further comprises a applying a delay after data acquisition for the recovery of Mz prior to a subsequent shot.

11. A method for performing fast three dimensional (3D) T₂ weighted imaging of a target tissue, comprising: acquiring image data from a target tissue site with at least one interleaved imaging shot; said imaging shot comprising a data acquisition via one or more pulses directed at the target tissue at a first flip angle (α_{high}) and one or more pulses directed at the target tissue at a second flip angle (α_{low}); wherein the first flip angle (α_{high}) is larger than the second flip angle (α_{low}), and the first flip angle (α_{high}) is less than 180°; and transforming the acquired image data into a 3D T₂-weighted image as a function of the at least one interleaved shot.

12. The method of any preceding embodiment, wherein the shot comprises a plurality of ramping pulses to smoothly ramp down from the first flip angle to the second flip angle.

13. The method of any preceding embodiment, wherein the image data is acquired in 3D Cartesian k-space in a ky-kz plane to encode the target tissue using a spiral-out phase encode ordering.

14. The method of any preceding embodiment, wherein spiral-out phase encode ordering comprises an acquisition pattern configured to initially acquire centrally located 3D low spatial frequency k-space lines, and subsequently moves outward in a spiral pattern to acquire high spatial frequency k-space lines.

15. The method of any preceding embodiment: wherein outer-most k-space lines are acquired with a steady-state free precession (bSSFP) signal and concomitant T₂/T₁ weighting; and wherein centrally-located k-space lines are acquired with transient bSSFP signal and T₂ weighting.

16. The method of any preceding embodiment, wherein the low frequency k-space lines are acquired with at flip angle of α_{high}.

17. The method of any preceding embodiment: wherein image data is acquired with a plurality of interleaved shots; and wherein the number of interleaved shots is a controllable parameter configured to improve a point spread function (PSF) of the generated image.

18. The method of any preceding embodiment, wherein the shot further comprises a series of preparation pulses prior to acquiring the image data; the series of preparation pulses having a flip angle that increases to one or more preparation pulses at a flip angle of α_{high}.

19. The method of claim 18, wherein the series of preparation pulses ramps from a preparation pulse starting at a flip angle between 0° and α_{high/2} followed with a series of preparation pulses at increasing flip angles that are followed by one or more preparation pulses at a flip angle of α_{high}.

20. The method of any preceding embodiment, wherein the shot further comprises a applying a delay after data acquisition for the recovery of Mz prior to a subsequent shot.

21. An apparatus for performing fast three dimensional (3D) T₂ weighted imaging of a target tissue, comprising: (a) a computer processor; and (b) a non-transitory computer-readable memory storing instructions executable by the computer processor; (c) wherein said instructions, when executed by the computer processor, perform steps comprising: (i) acquiring image data from a target tissue site with at least one interleaved imaging shot; (ii) said imaging shot comprising data acquisition via one or more pulses directed at the target tissue at a first flip angle (α_{high}), followed by a plurality of pulses with steadily decreasing flip angles, and concluded with one or more pulses directed at the target tissue at a second flip angle (α_{low}), the first flip angle having a value less than 180°; (iii) wherein the imaging shot further comprises a series of preparation pulses prior to acquiring the image data, the series of preparation pulses having a flip angle that increases to one or more preparation pulses at a flip angle of α_{high}; (iv) wherein the image data is acquired in 3D Cartesian k-space in a ky-kz plane to encode the target tissue with an acquisition pattern configured to initially acquire centrally located 3D low spatial frequency k-space lines, and subsequently moves outward in a spiral pattern to acquire high spatial frequency k-space lines; and (v) transforming the acquired image data into a 3D T2-weighted image as a function of the at least one interleaved shot.

22. The apparatus of any preceding embodiment: wherein outer-most k-space lines are acquired with a steady-state free precession (bSSFP) signal and concomitant T₂/T₁ weighting; and wherein centrally-located k-space lines are acquired with transient bSSFP signal and T₂ weighting.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

TABLE 1
Prostate imaging parameters for the different sequences.

| | 2D FSE | 3D FSE | 3D T₂-TIDE | 3D bSSFP |
|---|---|---|---|---|
| FOV (mm) | 200 × 200 | 200 × 200 | 200 × 200 | 200 × 200 |
| Resolution (mm) | 0.6 × 0.6 × 3.0 | 0.9 × 0.8 × 1.5 | 0.9 × 0.8 × 1.5 | 0.9 × 0.8 × 1.5 |
| Acquisition matrix | 320 × 310 | 256 × 230 | 256 × 230 | 256 × 230 |
| Phase oversampling (%) | 100% | 100% | 100% | 0% |
| Slice oversampling (%) | — | 20% | 20% | 20% |
| Slice thickness (mm) | 3.0 | 1.5 | 1.5 | 1.5 |
| Interpolated Slices | 20 | 60 | 60 | 60 |
| Slices | 20 | 48 | 48 | 48 |
| BW (Hz/px) | 200 | 315 | 930 | 930 |
| Flip Angle | 90°/150° | 90°/110° | VFA | 30-35° |
| PE direction | R to L | R to L | R to L | A to P |
| TR/TE (ms) | 4000/101 | 2200/200 | 4.84/2.42 | 4.56/2.28 |
| Echo spacing (ms) | 11.2 | 6.14 | 4.84 | 4.56 |
| Echo Train Duration (ms) | 280 | 565 | 1112 | — |
| GRAPPA factor/Ref lines | 2/32 | 2/24 | 2/24 | — |
| Partial Fourier | — | ~6/8 | 6/8 | — |
| Averages | 2 | 2 | 2 | 1 |
| T_{acq}(min) | 3:38 | 7:02 | 2:54 | 0:56 |
| SAR (W/kg) | 1.5 ± 0.2 | 1.5 ± 0.2 | 1.6 ± 0.2 | 1.8 ± 0.3 |
| Delay time,t_{D}(ms) | 3720 | 1635 | 1635 | — |
| Nₛₕₒₜₛ | — | — | 24 | — |

What is claimed is:

1. An apparatus for performing fast three dimensional (3D) T₂ weighted imaging of a target tissue, comprising:
(a) a computer processor; and
(b) a non-transitory computer-readable memory storing instructions executable by the computer processor;
(c) wherein said instructions, when executed by the computer processor, perform steps comprising:
(i) acquiring image data from a target tissue site with at least one interleaved imaging shot;
(ii) said imaging shot comprising data acquisition via one or more pulses directed at the target tissue at a first flip angle (α_{high}) and one or more pulses directed at the target tissue at a second flip angle (α_{low});
(iii) wherein the first flip angle (α_{high}) is larger than the second flip angle (α_{low}), and the first flip angle (α_{high}) is less than 180°; and
(iv) generating a 3D T₂-weighted image from the acquired image data as a function of the at least one interleaved shot.

2. The apparatus of claim 1, wherein the shot comprises a plurality of ramping pulses to smoothly ramp down from the first flip angle to the second flip angle.

3. The apparatus of claim 1, wherein the image data is acquired in 3D Cartesian k-space in a k_{y}-k_{z} plane to encode the target tissue using a spiral-out phase encode ordering.

4. The apparatus of claim 3, wherein spiral-out phase encode ordering comprises an acquisition pattern configured to initially acquire centrally located 3D low spatial frequency k-space lines, and subsequently moves outward in a spiral pattern to acquire high spatial frequency k-space lines.

5. The apparatus of claim 4:
wherein outer-most k-space lines are acquired with a steady-state free precession (bSSFP) signal and concomitant T₂/T₁ weighting; and
wherein centrally-located k-space lines are acquired with transient bSSFP signal and T₂ weighting.

6. The apparatus of claim 5, wherein the low frequency k-space lines are acquired with at a flip angle of α_{high}.

7. The apparatus of claim 1:
wherein image data is acquired with a plurality of interleaved shots; and
wherein the number of interleaved shots is a controllable parameter configured to improve a point spread function (PSF) of the generated image.

8. The apparatus of claim 1:
wherein the shot further comprises a series of preparation pulses prior to acquiring the image data;
the series of preparation pulses having a flip angle that increases to one or more preparation pulses at a flip angle of α_{high}.

9. The apparatus of claim 8, wherein the series of preparation pulses ramps from a preparation pulse starting at a flip angle between 0° and α_{high}/2 followed with a series of preparation pulses at increasing flip angles that are followed by one or more preparation pulses at a flip angle of α_{high}.

10. The apparatus of claim 1, wherein the shot further comprises a applying a delay after data acquisition for the recovery of Mz prior to a subsequent shot.

11. A method for performing fast three dimensional (3D) T₂ weighted imaging of a target tissue, comprising:
acquiring image data from a target tissue site with at least one interleaved imaging shot;
said imaging shot comprising a data acquisition via one or more pulses directed at the target tissue at a first flip angle (α_{high}) and one or more pulses directed at the target tissue at a second flip angle (α_{low});
wherein the first flip angle (α_{high}) is larger than the second flip angle (α_{low}), and the first flip angle (α_{high}) is less than 180°; and
transforming the acquired image data into a 3D T₂-weighted image as a function of the at least one interleaved shot.

12. The method of claim 11, wherein the shot comprises a plurality of ramping pulses to smoothly ramp down from the first flip angle to the second flip angle.

13. The method of claim 11, wherein the image data is acquired in 3D Cartesian k-space in a k_{y}-k_{z} plane to encode the target tissue using a spiral-out phase encode ordering.

14. The method of claim 13, wherein spiral-out phase encode ordering comprises an acquisition pattern configured to initially acquire centrally located 3D low spatial frequency k-space lines, and subsequently moves outward in a spiral pattern to acquire high spatial frequency k-space lines.

15. The method of claim 14:
wherein outer-most k-space lines are acquired with a steady-state free precession (bSSFP) signal and concomitant T₂/T₁ weighting; and
wherein centrally-located k-space lines are acquired with transient bSSFP signal and T2 weighting.

16. The method of claim 15, wherein the low frequency k-space lines are acquired with at flip angle of α_{high}.

17. The method of claim 11:
wherein image data is acquired with a plurality of interleaved shots; and
wherein the number of interleaved shots is a controllable parameter configured to improve a point spread function (PSF) of the generated image.

18. The method of claim 11, wherein the shot further comprises a series of preparation pulses prior to acquiring the image data;
the series of preparation pulses having a flip angle that increases to one or more preparation pulses at a flip angle of α_{high}.

19. The method of claim 18, wherein the series of preparation pulses ramps from a preparation pulse starting at a flip angle between 0° and α_{high}/2 followed with a series of preparation pulses at increasing flip angles that are followed by one or more preparation pulses at a flip angle of α_{high}.

20. The method of claim 11, wherein the shot further comprises a applying a delay after data acquisition for the recovery of Mz prior to a subsequent shot.

21. An apparatus for performing fast three dimensional (3D) T₂ weighted imaging of a target tissue, comprising:
(a) a computer processor; and
(b) a non-transitory computer-readable memory storing instructions executable by the computer processor;
(c) wherein said instructions, when executed by the computer processor, perform steps comprising:
(i) acquiring image data from a target tissue site with at least one interleaved imaging shot;
(ii) said imaging shot comprising data acquisition via one or more pulses directed at the target tissue at a first flip angle (α_{high}), followed by a plurality of pulses with steadily decreasing flip angles, and concluded with one or more pulses directed at the target tissue at a second flip angle (α_{low}), the first flip angle having a value less than 180°;
(iii) wherein the imaging shot further comprises a series of preparation pulses prior to acquiring the image data, the series of preparation pulses having a flip angle that increases to one or more preparation pulses at a flip angle of α_{high};
(iv) wherein the image data is acquired in 3D Cartesian k-space in a k_{y}-k_{z} plane to encode the target tissue with an acquisition pattern configured to initially acquire centrally located 3D low spatial frequency k-space lines, and subsequently moves outward in a spiral pattern to acquire high spatial frequency k-space lines; and
(v) transforming the acquired image data into a 3D T₂-weighted image as a function of the at least one interleaved shot.

22. The apparatus of claim 21:
wherein outer-most k-space lines are acquired with a steady-state free precession (bSSFP) signal and concomitant T₂/T₁ weighting; and
wherein centrally-located k-space lines are acquired with transient bSSFP signal and T₂ weighting.
